(19) United States
(12) Patent Application Publication
(10) Pub. No.: US 2025/0126708 A1
(43) Pub. Date: Apr. 17, 2025

(54) MICROPARTICLE-FILLED LAMINATE MATERIAL

(71) Applicant: Dell Products L.P., Round Rock, TX (US)

(72) Inventors: Sandor T. FARKAS, Round Rock, TX (US); Steven R. ETHRIDGE, Austin, TX (US); Bhyrav M. MUTNURY, Austin, TX (US)

(73) Assignee: Dell Products L.P., Round Rock, TX (US)

(21) Appl. No.: 18/485,704

(22) Filed: Oct. 12, 2023

(51) Int. Cl. H05K 1/03

(52) U.S. Cl. CPC H05K 1/0373; H05K 2201/0254

(57) ABSTRACT

A circuit board may include at least one layer of resin and a plurality of microparticles distributed throughout the at least one layer of resin.

### TECHNICAL FIELD

The present disclosure relates in general to information handling systems, and more particularly to systems and methods for minimizing skew and loss in a circuit board, in particular by filling laminate material used in manufacturing of circuit boards with microparticles.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems may often use one or more circuit boards. A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

Traditional circuit boards are often constructed using layers of resin material with glass fibers woven therein, for example as depicted in FIG. 4. FIG. 4 illustrates an example side cross-sectional elevation view of selected portions of a circuit board 10, as is known in the art. As shown in FIG. 4, circuit board 10 may include at least one layer of resin 12 with glass fibers 14 woven in a crisscross pattern. Further, traces 16 may be formed on a surface of a top layer of circuit board 10. Glass fibers 14 may be provided to provide mechanical strength to circuit board 10, but the presence of glass fibers 14 may have disadvantages. For example, differences in dielectric constant between resin 12 and glass fibers 14 may cause signal skew when differential pairs of traces 16 are routed proximate to woven glass fibers 14. Further, the dissipation factors of resin 12 and glass fibers 14 may lead to signal loss at higher frequencies. Further, with increasing densities of signal routing in circuit boards, it is not always possible to route traces 16 to avoid proximity to glass fibers 14.

### SUMMARY

In accordance with the teachings of the present disclosure, the disadvantages and problems associated with existing approaches to circuits boards may be reduced or eliminated.

In accordance with embodiments of the present disclosure, a circuit board may include at least one layer of resin and a plurality of microparticles distributed throughout the at least one layer of resin.

In accordance with these and other embodiments of the present disclosure, an information handling system may include a processor and an information handling resource communicatively coupled to the processor and comprising a circuit board including at least one layer of resin and a plurality of microparticles distributed throughout the at least one layer of resin.

In accordance with these and other embodiments of the present disclosure, a method for making a circuit board, may include forming at least one layer of the circuit board with resin and distributing a plurality of microparticles throughout the at least one layer of resin.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIG. 2 illustrates an example side cross-sectional elevation view of selected portions of a circuit board, in accordance with embodiments of the present disclosure;

FIG. 3 illustrates an example side cross-sectional elevation view of selected portions of another circuit board, in accordance with embodiments of the present disclosure; and

FIG. 4 illustrates an example side cross-sectional elevation view of selected portions of a circuit board, as is known in the art.

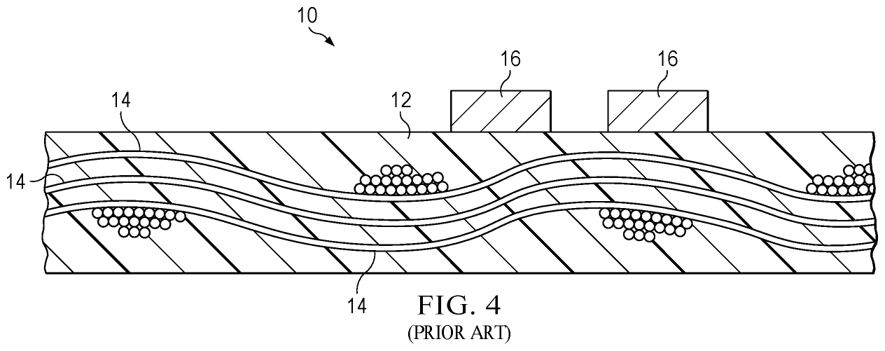

### DETAILED DESCRIPTION

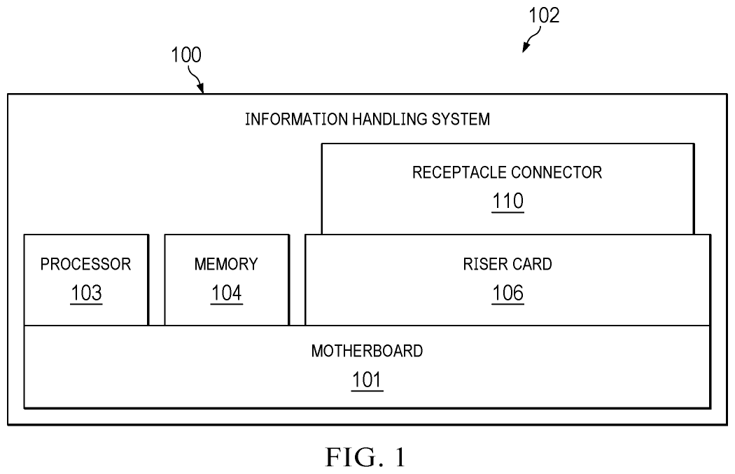

Preferred embodiments and their advantages are best understood by reference to FIGS. 1 through 3 wherein like numbers are used to indicate like and corresponding parts.

For the purposes of this disclosure, an information handling system may include any instrumentality or aggregate of instrumentalities operable to compute, classify, process, transmit, receive, retrieve, switch, store, originate, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and vary in size, shape, performance, functionality, and price. The information handling system may include memory, one or more processing resources such as a central processing unit (“CPU”), microcontroller, or hardware or software control logic. Additional components of the information handling system may include one or more devices, one storage or more communications ports for communicating with external devices as well as various input/output (“I/O”) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, and/or any other components and/or elements of an information handling system.

For the purposes of this disclosure, circuit boards may broadly refer to printed circuit boards (PCBs), printed wiring boards (PWBs), printed wiring assemblies (PWAS), etched wiring boards, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIG. 1 illustrates a block diagram of selected components of an example information handling system 102. In some embodiments, information handling system 102 may comprise a server. In other embodiments, information handling system 102 may comprise networking equipment for facilitating communication over a communication network. In yet other embodiments, information handling system 102 may comprise a personal computer, such as a laptop, notebook, or desktop computer.

As shown in FIG. 1, information handling system 102 may include a chassis 100 that houses a motherboard 101, a processor 103 coupled to motherboard 101, a memory 104 coupled to motherboard 101, a riser card 106 mechanically and electrically coupled to motherboard 101, and a receptacle connector 110 mechanically coupled to riser card 106.

Chassis 100 may include any suitable housing or enclosure configured to house the various components of information handling system 102, and may be constructed from metal, plastic, and/or any other suitable material.

Motherboard 101 may comprise a circuit board configured to provide structural support for one or more information handling resources of information handling system 102 and/or electrically couple one or more of such information handling resources to each other and/or to other electric or electronic components external to information handling system 102.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in a storage resource, memory system 104, and/or another component of information handling system 102.

Memory 104 may be communicatively coupled to processor 103 and may comprise any system, device, or apparatus operable to retain program instructions or data for a period of time (e.g., computer-readable media). Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off. In particular embodiments, memory 104 may comprise dynamic random access memory (DRAM).

Riser card 106 may comprise a circuit board enabling the option for additional expansion cards to be coupled to motherboard 101. Riser card 106 may be coupled to motherboard 101 via an edge connector (not explicitly shown in FIG. 1) that mechanically and electrically couples to a corresponding receptacle connector of motherboard 101 (not explicitly shown in FIG. 1).

A receptacle connector 110 may comprise any system, device, or apparatus fixedly mounted relative to riser card 106 and may be constructed to mechanically couple a corresponding expansion card (not explicitly shown in FIG. 1) within such receptacle connector 110 and to electrically couple such expansion card to motherboard 101, processor 103, and/or other components of information handling system 102. Connector 110 may comprise a socket including a receptacle slot or other opening configured to removably receive a corresponding mating edge connector of an expansion card.

In addition to motherboard 101, processor 103, memory 104, riser card 106, and receptacle connector 110, information handling system 102 may include one or more other information handling resources.

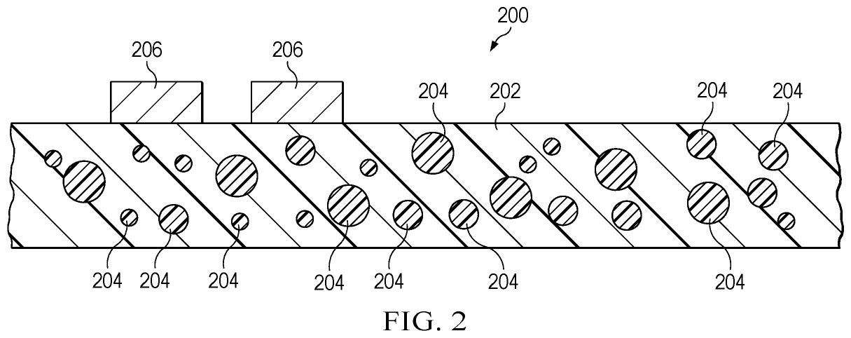

FIG. 2 illustrates an example side cross-sectional elevation view of selected portions of a circuit board 200, in accordance with embodiments of the present disclosure. In some embodiments, circuit board 200 or a circuit board similar to circuit board 200 may be used to implement motherboard 101, memory 104, riser card 106, and/or any other suitable information handling resource of information handling system 102.

As shown in FIG. 2, circuit board 200 may include at least one layer of resin 202 filled with a plurality of microparticles 204. Further, traces 206 may be formed on a surface of a top layer of circuit board 200.

A microparticle 204 may comprise any suitable particle) or object. In some embodiments, such as shown in FIG. 2, a microparticle 204 may be spherical (or approximately spherical in shape, due to manufacturing tolerances) in shape (e.g., a microsphere). In these and other embodiments, a microparticle 204 may have another three-dimensional shape, including without limitation a cube or other polyhedron.

In some embodiments, a microparticle 204 may have a dimension ranging in size between 20 μm and 200 μm. A microparticle 204 may be made of any suitable material, including glass or plastic. In some embodiments, the material used may be selected to minimize signal loss of electrical conduits (e.g., traces 206) in circuit 200.

In these and other embodiments, a microparticle 204 may be solid (e.g., the entire volume of such microparticle 204 is made of the same material). In some embodiments, a microparticle 204 may be hollow. In embodiments in which a microparticle is hollow, its internal volume may be filled with a gas. In other embodiments in which a microparticle is hollow, its internal volume may comprise a vacuum.

One advantage of filling resin 202 with microparticles 204 as described above, particularly in those embodiments in which the internal volumes of microparticles 204 comprise air or a vacuum, is that resin volume of traditional approaches may be replaced with air, thus reducing (as compared to traditional approaches) signal losses attributable to resin. Further, if sized appropriately, microparticles 204 may be randomly distributed within resin 202, eliminating issues associated with weaving of glass fibers in traditional approaches, thus potentially reducing (as compared to traditional approaches) signal losses and signal skew.

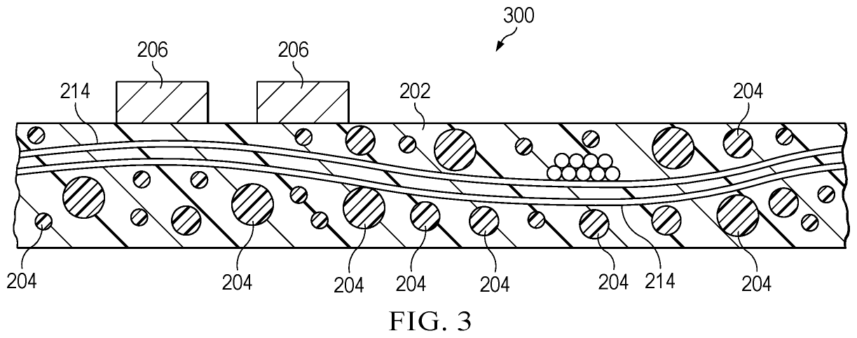

FIG. 3 illustrates an example side cross-sectional elevation view of selected portions of another circuit board 300, in accordance with embodiments of the present disclosure. In some embodiments, circuit board 300 or a circuit board similar to circuit board 300 may be used to implement motherboard 101, memory 104, riser card 106, and/or any other suitable information handling resource of information handling system 102. Circuit board 300 depicted in FIG. 3 may be similar in many respects to circuit board 200 depicted in FIG. 2, and thus only certain differences between circuit board 200 and circuit board 300 may be described herein. In particular, to provide for mechanical strength of circuit board 200, a sparse amount of glass fibers 214 (e.g., significantly less than that used in traditional approaches) may be woven within resin 202.

For the purposes of clarity and exposition, circuit boards 200 and 300 are depicted with only a single resin layer. However, it is understood that circuit boards 200 and 300 may include a plurality of layers, any number of which may include microparticles 204 distributed throughout. Further, although a plurality of microparticles 204 distributed throughout a layer of resin 202 may be of varying sizes, as shown in FIGS. 2 and 3, in some embodiments, a plurality of microparticles may all be approximately the same size.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

What is claimed is:

1. A circuit board comprising:
at least one layer of resin; and
a plurality of microparticles distributed throughout the at least one layer of resin.

2. The circuit board of claim 1, wherein at least one of the plurality of microparticles is solid throughout.

3. The circuit board of claim 1, wherein at least one of the plurality of microparticles is hollow.

4. The circuit board of claim 3, wherein an internal volume of the at least one of the plurality of microparticles is filled with a gas.

5. The circuit board of claim 3, wherein an internal volume of the at least one of the plurality of microparticles comprises a vacuum.

6. The circuit board of claim 1, wherein at least one of the plurality of microparticles is made of glass.

7. The circuit board of claim 1, wherein at least one of the plurality of microparticles is made of plastic.

8. The circuit board of claim 1, wherein at least one of the plurality of microparticles is a microsphere.

9. An information handling system comprising:
a processor; and
an information handling resource communicatively coupled to the processor and comprising a circuit board including:
at least one layer of resin; and
a plurality of microparticles distributed throughout the at least one layer of resin.

10. The information handling system of claim 9, wherein at least one of the plurality of microparticles is solid throughout.

11. The information handling system of claim 9, wherein at least one of the plurality of microparticles is hollow.

12. The information handling system of claim 11, wherein an internal volume of the at least one of the plurality of microparticles is filled with a gas.

13. The information handling system of claim 11, wherein an internal volume of the at least one of the plurality of microparticles comprises a vacuum.

14. The information handling system of claim 9, wherein at least one of the plurality of microparticles is made of glass.

15. The information handling system of claim 9, wherein at least one of the plurality of microparticles is made of plastic.

16. The information handling system of claim 9, wherein at least one of the plurality of microparticles is a microsphere.

17. A method for making a circuit board, comprising:
forming at least one layer of the circuit board with resin; and
distributing a plurality of microparticles throughout the at least one layer of resin.

18. The method of claim 17, wherein at least one of the plurality of microparticles is solid throughout.

19. The method of claim 17, wherein at least one of the plurality of microparticles is hollow.

20. The method of claim 19, wherein an internal volume of the at least one of the plurality of microparticles is filled with a gas.

21. The method of claim 19, wherein an internal volume of the at least one of the plurality of microparticles comprises a vacuum.

22. The method of claim 17, wherein at least one of the plurality of microparticles is made of glass.

23. The method of claim 17, wherein at least one of the plurality of microparticles is made of plastic.

24. The method of claim 17, wherein at least one of the plurality of microparticles is a microsphere.
